(19) United States
(12) Patent Application Publication
(10) Pub. No.: US 2026/0234787 A1
(43) Pub. Date: Aug. 13, 2026

(54) SILICON-CONTAINING TRANSITION-METAL BORIDE EVAPORATION SOURCE

(71) Applicant: PLANSEE COMPOSITE MATERIALS GMBH, Lechbruck am See (DE)

(72) Inventors: Szilard KOLOZSVARI, Lechbruck am See (DE); Peter POLCIK, Lechbruck am See (DE); Marcus WOLFF, Lechbruck am See (DE)

(21) Appl. No.: 19/154,902

(22) PCT Filed: Jan. 15, 2024
(86) PCT No.: PCT/EP2024/050777

§ 371 Date: Aug. 8, 2025

(30) Foreign Application Priority Data
Feb. 8, 2023 (AT) GM50014/2023

(51) Int. Cl. C23C 14/34; C23C 14/32

(52) U.S. Cl. CPC C23C 14/3414; C23C 14/325

(57) ABSTRACT

An evaporation source contains a target material containing one or more borides selected from the group of TiB₂, W₂B₅, TaB₂, VB₂, NbB₂, CrB₂, MoB and HfB₂ and one or more silicon-containing compounds selected from the group of TiSi₂, Ti₅Si₃, CrSi₂, Cr₅Si₃, Cr₃Si, CeSi₂, SiB₆, HfSi, Hf₅Si₄, Hf₃Si₂, NbSi₂, Nb₅Si₃, MoSi₂, Mo₅Si₃, Mo₃Si, ZrSi, Zr₂Si, Zr₅Si₃, Zr₅Si₄, Zr₃Si₂, TaSi₂, Ta₅Si₃, Ta₃Si, Ta₂Si, W₅Si₃ and WSi₂, in addition to unavoidable impurities. The content of the silicon in the target material amounts to 1-30 at %. A method for produces an evaporation source of this kind.

The present invention relates to an evaporation source for physical vapor deposition for depositing silicon-containing transition metal boride layers. The present invention further relates to a process for producing such an evaporation source.

Transition metal borides are known for their refractory properties, such as high melting temperatures in many cases above 3000° C., broad phase stability, high thermal conductivity and adequate thermal shock resistance. The continued interest in sustainable material applications and in the durability of high-performance components, for example machine elements in aircraft engines, calls for transition metal boride-based materials as a novel class of protective layers. There is a focus in particular on the high temperature resistance of such layers and strategies to improve the weak oxidation resistance of such layers are presently being developed.

It was found that the oxidation resistance of the abovementioned layers may be significantly improved through enrichment with silicon (see unpublished patent application PCT/EP2022/076328 and Thomas Glechner, High temperature oxidation resistance of physical vapor deposited HF—Si—B_{2±z} thin films, Corrosion Science, Vol. 205, 2022, https://doi.org/10.1016/j.corsci.2022.110413).

Enrichment with silicon was carried out on an experimental scale by placing silicon platelets on the surface of evaporation sources (targets) made of pure transition metal borides. The silicon content in the deposited layers was controlled by the number of platelets placed. However, this process has the disadvantage that the silicon content may be varied, but only roughly adjusted. Furthermore, targets in industrially utilized coating plants are typically arranged vertically so that mere placing of silicon platelets is not possible since these would fall off.

CN112323031 A relates to a corrosion-resistant layer composed of 3 to 14 at % Si, 30 to 33 at % Ti and 55 to 66 at % B. The layer is produced by simultaneous sputtering (co-sputtering) of two targets, wherein one target consists of silicon and the other target consists of titanium diboride. However, the disadvantage of this process is that the co-sputtering of two separate targets can lead to the formation of undesired multilayers when the parts to be coated (substrates) are rotated. Therefore applications employing co-sputtering have the disadvantage that in order to prevent formation of multilayers the substrates must not be moved. However, this so-called stationary coating method prevents economic industrial use of the technology to treat as many substrates as possible in one batch.

A further disadvantage of co-sputtering is that in some PVD coating plants the number of employed cathodes to which the targets are secured is limited, thus precluding the use of two or more targets composed of different materials.

JP2017218621 A relates to a target material containing Cr, Si and B and comprising a pure Si phase, a Cr₂B phase and a Cr mixed crystal phase. The Si content in the target material is 1 to 16.9 at % and the B content is preferably 2.5 at % to 7 at % or less. The target material is prepared by subjecting a powder mixture of silicon powder, boron powder and chromium powder to a plasma sintering process with electric discharge (SPS or spark plasma sintering). However, due to the direct use of silicon powder having a melting point of only slightly above 1400° C. this process is severely restricted in terms of process temperatures. High temperatures in the range of up to 2000° C. and above are necessary for sufficient densification of transition metal boride-containing target materials. However, these conditions result in liquefaction of the silicon, thus allowing material to escape during the pressing process and thus the precise composition of the target material cannot be controlled. The pressing tool may also be destroyed by the occurring hydrostatic pressure.

The object of the present invention is therefore the provision of an improved evaporation source of defined composition for improved production of silicon-enriched metal boride layers.

This object is solved by an evaporation source according to claim 1 and by a process for producing the evaporation source according to claim 10. Advantageous further embodiments of the invention are apparent from the dependent claims which are freely combinable with one another.

In the prior art processes for physical vapor deposition to produce the aforementioned layers are employed to a large extent. Physical vapor deposition (PVD) employs various techniques, for example evaporation, sputter deposition or cathodic arc deposition/arc source evaporation techniques.

Via physical processes, starting material in the form of a solid is transferred into the vapor phase/plasma state and subsequently deposited onto a substrate. In sputter deposition atoms are released from the solid body by bombardment of a surface of the evaporation source with high-energy ions. The material atomized in this way is distributed in the coating chamber and is deposited on a substrate to be coated. In the prior art such an evaporation source is also known as a sputtering target. In a cathodic arc deposition, the solid is evaporated by vacuum arc discharging and is deposited on the substrate. In the prior art such an evaporation source is also known as an arc cathode. In the context of the present disclosure the term evaporation source is to be understood as meaning sputtering targets and arc cathodes, or targets for short. Such targets comprise at least the target material and optionally a backplate attached thereto. To avoid problems in the deposition process, such as overheating caused by poor thermal conductivity of the target, instability of the process caused by the effect of the target on the quality of the vacuum during the coating process or locking of the arc during ablation of the target material caused by an inhomogeneous electrical conductivity of the target, the target material must have as high and homogeneous density as possible.

Evaporation sources made of ceramic materials, for example borides, carbides, nitrides and silicides, are therefore typically produced by hot pressing or spark plasma sintering. In the case of transition metal borides, which typically have high melting points in the range from about 2100° C. to 3300° C., extreme conditions and thus temperatures in a range from at least 1300° C., in particular 1500° C. to 2200° C., as well as pressures in the range from 20 to 80 MPa are necessary to achieve the required densification of the target material. This impedes as mentioned above the enrichment of the target material with the comparatively low-melting silicon.

The present invention achieves, through the use of specific starting materials in conjunction with specific production processes to produce evaporation sources having a suitable high density for PVD (physical vapor deposition) processes which have a defined silicon content and with which metal boride layers having a defined composition can be produced.

According to the present invention an evaporation source comprises a target material consisting of or produced from one or more borides selected from the group consisting of TiB₂, W₂B₅, TaB₂, VB₂, NbB₂, CrB₂, MoB and HfB₂ and one or more silicon-containing compounds selected from the group consisting of (melting points reported in parentheses) TiSi₂ (1480° C.), Ti₅Si₃ (2130° C.), CrSi₂ (1490° C.), Cr₅Si₃ (1680° C.), Cr₃Si (1770° C.), CeSi₂ (1620° C.), SiB₆ (1850° C.), HfSi (2142° C.), Hf₅Si₄ (2320° C.), Hf₃Si₂ (2480° C.), NbSi₂ (1940° C.), Nb₅Si₃ (2520° C.), MoSi₂ (2020° C.), MosSi₃ (2180° C.), Mo₃Si (2020° C.), ZrSi (2210° C.), Zr₂Si (1925° C.), Zr₅Si₃ (2180° C.), Zr₅Si₄ (2250° C.), Zr₃Si₂ (2215° C.), TaSi₂ (2040° C.), Ta₅Si₃ (2550° C.), Ta₃Si (2350° C.), Ta₂Si (2440° C.), W₅Si₃ (2372° C.) and WSi₂ (2141° C.) in addition to unavoidable impurities and wherein the proportion of the silicon in the target material is 1 at % to 30 at %.

The main advantage of the invention lies in the provision of the silicon in the target material in the form of high-melting compounds of silicon. The disadvantage of the markedly differing melting temperatures of silicon and the boron-containing compounds serving as the main constituent can be overcome through this. In the present invention high-melting silicon compounds having melting points close to 2000° C. and above are employed for the purposes of silicon enrichment. Thereby the occurrence of a liquid phase during production of the evaporation source by hot pressing can be avoided and simultaneously sufficient densification of the target material can be ensured. Through this a defined content of silicon in the target material can be set at a simultaneous high density of the target material. The starting materials coexist in the same target, whereby the formation of multilayers in the deposition process can be avoided. With the evaporation source of the present invention, it is possible to deposit homogeneous layers of defined composition, even in the case of a stationary process mode.

Another advantage of the invention is that silicides have a higher electrical conductivity than silicon carbides, nitrides, and oxides, which is important for optimal functionality of the target.

The target material can contain only a single boride or mixtures of several of the mentioned borides. Preferably, the one or several borides is/are selected from the group consisting of TiB₂, TaB₂, CrB₂, MoB and HfB₂, in particular HfB₂, TiB₂ and CrB₂ and mixtures thereof.

The target material may contain only a single silicon-containing compound or mixtures of several of the recited silicon-containing compounds. Preferably, the one or several silicon-containing compound(s) is/are selected from the group consisting of Ti₅Si₃, Cr₃Si, Cr₅Si₃, CeSi₂, SiB₆, HfSi, Hf₃Si₂, Hf₅Si₄, Nb₅Si₃, MoSi₂, Mo₅Si₃, Mo₃Si, ZrSi, Zr₅Si₃, Zr₅Si₄, Zr₃Si₂, TaSi₂, Ta₅Si₃, Ta₃Si, Ta₂Si, W₅Si₃ and WSi₂ and mixtures thereof.

Further preferred is/are one or several silicon-containing compound(s) selected from the group consisting of Ti₅Si₃, Cr₃Si, CeSi₂, SiB₆, HfSi, Hf₃Si₂, Hf₅Si₄, Nb₅Si₃, MoSi₂, Mo₅Si₃, Mo₃Si, Zr₅Si₃, ZrSi, TaSi₂, Ta₅Si₃, Ta₃Si, W₅Si₃ and WSi₂ and mixtures thereof.

Particularly preferred compositions of the target material are selected from the group consisting of CrB₂/CrSi₂, CrB₂/MoSi₂; HfB₂/CeSi₂; HfB₂/MoSi₂; TiB₂/MoSi₂; TiB₂/TaSi₂; TiB₂/Ti₅Si₃; TiB₂/Ti₅Si₃/SiB₆ and TiB₂/TiSi₂.

According to the present invention unavoidable impurities are to be understood as meaning metallic and non-metallic elements which cannot be removed during production of the starting materials, the powders of the borides and silicon-containing compounds, and are therefore present in the target material. Preferably, the values for impurities due to oxygen in the starting materials are in the range from 2000-10 000 ppm in total. Further non-metallic impurities such as carbon or nitrogen are present in the range of up to 2000 ppm in total. Metallic impurities are present in total in the starting materials below 5000 ppm, preferably below 2000 ppm.

The chemical qualitative and quantitative analysis of the starting materials and the target material may be determined by ICP-OES and ICP-OMS.

During densification of the material mixed phases of the employed materials may in some cases be formed. For example, in the case of the combination TiB₂/MoSi₂ small amounts of an Mo₂Ti₃Si₃ phase are formed aside from the TiB₂ phase and the MoSi₂ phase. The proportion of mixed phases in the target material is characteristic for the present invention and can be kept very low on account of the preferred production process using spark plasma sintering. The proportion of mixed phases formed in the densification process may be quantified by EDX on cross-sections of the target using an SEM and is preferably below 20% of the measured surface area based on statistically sound measurements, more preferably below 10%. For the purposes of defining the chemical composition of the evaporation source of the present invention these mixed phases are considered as encompassed in the form of the starting materials. In other words, this means that for example a processed target material which after hot pressing of a powder mixture of TiB₂/MoSi₂ contains aside from the TiB₂ phase and the MoSi₂ phase also small amounts of a Mo₂Ti₃Si₃ phase, is defined as consisting of TiB₂/MoSi₂.

According to the invention the proportion of silicon in the target material is in a range from 1 at % to 30 at %. The proportion of silicon may be adjusted by targeted selection and sample weight of the starting materials. Preferably, the proportion of silicon in the target material is in a range from 8 to 20 at % and more preferably in a range from 10 to 15 at %.

It is known that in physical vapor deposition of layers using boron-containing targets a small portion of the boron may be lost. To compensate, the target material according to the invention may be enriched with SiB₆. Thus, the loss of boron may be compensated during deposition without introducing further metallic elements into the target material or a layer deposited therefrom. For these purposes it is advantageous in the present invention when the evaporation source comprises at least two silicon-containing compounds, wherein one is SiB₆. Preferably, the proportion of SiB₆ in this embodiment is in a range from 10 to 50 mol %. Particularly preferable the proportion of SiB₆ is in a range of 15-30 mol %. All amounts of the invention specified in mol % refer to 100 mol % of the total target material.

In one embodiment the target material of the present invention may thus consist as a ternary system of compounds of precisely one of the metals mentioned herein, boron and silicon. In an alternative embodiment the target material of the present invention may consist of compounds which in addition to boron and silicon contain several metals, preferably as a quaternary system of two of the recited metals, in the respectively bonded form.

The target material of the evaporation source according to the invention characteristically has a very high density. Preferably the density is at least 95% of the theoretical density, preferably 98%, to 100% of the theoretical density.

By definition, the theoretical density which applies to the respective composition of the target material is calculated from the mole fraction-weighted average of the theoretical densities of the individual phase constituents. The actual density of the target material is determined by the Archimedes principle.

During coating the evaporation sources are subjected to thermal stress by the plasma, an electric arc and optionally by a heating means in the coating chamber. To avoid excessive heating of the evaporation sources these are typically cooled from the rear side. Cooling may be effected either by direct water cooling of the reverse side of the target material or by indirect cooling via a rigid support element joined to the target material in the form of a backplate. The support element can be produced in a single-stage process in the same densification process in which the target material is densified/sintered, from a specially manufactured powder mixture or already solid backing plate/bulk material or also later, after the end of the densification process of the target material as bulk material by means of a suitable high or low temperature bonding process.

Materials that are particularly suitable for the support are pure metals such as titanium, copper, molybdenum, tungsten, tantalum or alloys or composites of these metals. Preferred are molybdenum-, tungsten- or tantalum-based alloys, wherein the term based alloy is to be understood as meaning an alloy which, in addition to further metals, contains more than 50 at % of the base metal giving its name. Molybdenum-based alloys, tungsten-based alloys or tantalum-based alloys are also suitable as materials for a support element because they have the advantageous combination of properties of sufficiently high thermal conductivity, a high modulus of elasticity, i.e. high rigidity, and a relatively low coefficient of thermal expansion. With regard to industrial mass production, support elements made of molybdenum, titanium, molybdenum-based alloys and titanium-based alloys are particularly preferred.

The evaporation source of the present invention is suitable for industrial application in coating plants. Evaporation sources according to the invention may be either plate-shaped (with a round or rectangular format) or tubular.

In a preferred embodiment the evaporation source is formed with a backplate as a support element, especially preferred with the following dimensions:
round formats typically have diameters of 50 mm to 350 mm and a thickness of 5 to 40 mm with support elements of corresponding diameter and a thickness of 2 to 15 mm,
rectangular formats typically have a width of 50 mm to 300 mm and a thickness of 5 mm to 40 mm and a length of up to 1000 mm. In particular embodiments these formats may be multi-part, wherein several segments of the densified target material are arranged on a common support element. An associated support element typically has the following dimensions: 50-300 mm width, 2-10 mm thickness and up to 1000 mm length.

Bonding techniques for connecting the target material to the support element are known in the prior art. Typically the target material is connected to the support using indium, but also by hard or soft solders known in the prior art.

Examples of soft solders are tin-silver-based solders and tin-copper-based solders. Examples of hard solders are silver, brass and phosphorus solders. In a preferred embodiment the target materials are joined to the backplates via a silver-based solder with proportions of titanium, copper and/or nickel. It is not relevant how these solders are applied. There are two options for providing the solder: the use of a commercially available solder foil, which is placed between the target material and the backplate during the soldering process or the application of the solder-forming elements by a spraying process, loke for example cold gas spraying (CGS), on either the backplate or on a corresponding surface of the target material which are then later joined to one another.

A further method of joining the target material to a suitable backplate may be effected during the actual compaction process in the spark plasma sintering or hot pressing apparatus. To this end the backplate is placed in the apparatus either as a previously compacted component or in the form of a powder of its constituents and compacted simultaneously with the target material. A further joining method is that of diffusion bonding a backplate in the form of a bulk material to the compacted target material in the form of a bulk material in a hot pressing or SPS apparatus.

The present invention also relates to a process for producing the evaporation sources described herein, in particular the target material.

The process according to the invention for producing an evaporation source described herein comprises at least the steps of:
providing a powder mixture of the target material from at least one boride and at least one silicon-containing compound
uniaxially densifying the powder mixture in a pressing tool at such temperatures that the powder mixture is sintered into a solid without the formation of liquid phases.

To prepare the powder mixture the at least one boride and the at least one silicon-containing compound are employed in the form of their commercially available powders. The average particle diameter of these starting powders defined by the D50 value of a size distribution measurement by laser diffraction particle size analysis is typically 1 μm to 50 μm, preferably 2 μm to 20 μm, for the borides and typically 2 μm to 100 μm, preferably 2 μm to 20 μm, for the silicon-containing compounds.

To adjust the desired chemical composition and homogeneity the starting powders are weighed out in the required ratio and mixed for several minutes, preferably in a freefall mixer, preferably with addition of isopropanol and grinding balls.

The homogenized powder mixture is optionally dried in a furnace and filled into a graphite tool, which is introduced into a hot press or SPS apparatus and uniaxially densified using the upper and lower punch of the press/SPS apparatus.

Uniaxial densification is typically carried out at a pressure in a range from 20 to 80 MPa, preferably at a pressure in a range from 25 to 60 MPa, at temperatures in the range from 1300° C. to 2200° C., preferably at temperatures in the range from 1450° C. to 2200° C., more preferably in the range from 1500° C. to 2200° C., more preferably in the range from 1650° C. to 2200° C. and more preferably in the range from 1800° C. to 2200° C. In the technical field of the present invention this operation is referred to as hot pressing (HP). As mentioned, it is also possible to subject the powder mixture to electric current during the pressing operation. As a subtype of hot pressing processes in this spark plasma sintering process the powder mixture is heated in a very short period of time by the current passing through it due to the electrical resistance of the powder mixture. The use of this process supports the suppression of the formation of further compounds (mixed phases) of the starting components and allows production of high-density targets at very short process times.

Preferably, therefore, the densification process of the target material is performed in an SPS plant with the application of electric current. Preferably, the powder mixture is brought to operating pressure and temperature within 5 to 90 minutes, preferably 10 to 60 minutes, in particular 10 to 30 minutes, with simultaneous increasing pressurization and is densified under these conditions over a period of 5 to 90 minutes, preferably 15 to 60 minutes in such a way that the powder mixture is sintered to a solid without the formation of liquid phases.

Further advantages and usefulness of the invention are apparent from the following production examples.

| | Boride/silicide; ratio in mol %; backplate; | % Theoretical | Temperature | Pressure |
|---|---|---|---|---|
| Ex. | target format in mm with support element | density | in ° C. | in MPa |
| 1 | CrB₂/CrSi₂; 80/20; Cu; Ø75 × 6 | 99.02 | 1300 | 35 |
| 2 | CrB₂/CrSi₂; 90/10; Cu; Ø75 × 6 | 99.42 | 1300 | 35 |
| 3 | CrB₂/MoSi₂; 70/30; Cu; Ø75 × 6 | 100.00 | 1600 | 35 |
| 4 | CrB₂/MoSi₂; 80/20; Cu; Ø75 × 6 | 100.00 | 1600 | 35 |
| 5 | CrB₂/MoSi₂; 82.5/17.5; Cu; Ø75 × 6 | 100.00 | 1550 | 35 |
| 6 | CrB₂/MoSi₂; 85/15; Cu; Ø75 × 6 | 99.52 | 1550 | 35 |
| 7 | CrB₂/MoSi₂; 87.5/12.5; Cu; Ø75 × 6 | 100.00 | 1525 | 35 |
| 8 | CrB₂/MoSi₂; 90/10; Cu; Ø75 × 6 | 99.44 | 1700 | 35 |
| 9 | CrB₂/MoSi₂; 90/10; Mo; Ø160 × 12 | 99.07 | 1500 | 35 |
| 10 | HfB₂/CeSi₂; 60/40; Cu; Ø75 × 6 | 100.00 | 1650 | 35 |
| 11 | HfB₂/CeSi₂; 70/30; Cu; Ø75 × 6 | 97.62 | 1620 | 35 |
| 12 | HfB₂/CeSi₂; 90/10; Cu; Ø75 × 6 | 98.85 | 2050 | 35 |
| 13 | HfB₂/MoSi₂; 70/30; Cu; Ø75 × 6 | 98.89 | 1600 | 35 |
| 14 | HfB₂/MoSi₂; 80/20; Cu; Ø75 × 6 | 100.00 | 1650 | 35 |
| 15 | TiB₂/MoSi₂; 70/30; Cu; Ø75 × 6 | 98.82 | 1800 | 35 |
| 16 | TiB₂/MoSi₂; 80/20; Cu; Ø75 × 6 | 100.00 | 1800 | 35 |
| 17 | TiB₂/MoSi₂; 80/20; Mo; Ø160 × 12 | 100.00 | 1800 | 35 |
| 18 | TIB₂/MoSi₂; 85/15; Cu; Ø75 × 6 | 100.00 | 1800 | 35 |
| 19 | TiB₂/MoSi₂; 90/10; Cu; Ø75 × 6 | 98.53 | 1750 | 35 |
| 20 | TiB₂/TaSi₂; 80/20; Cu; Ø75 × 6 | 95.37 | 1675 | 35 |
| 21 | TiB₂/TaSi₂; 90/10; Cu; Ø75 × 6 | 96.75 | 1750 | 35 |
| 22 | TiB₂/TisSi₃; 79.1/20.9; Cu; Ø75 × 6 | 98.93 | 1675 | 35 |
| 23 | TiB₂/TisSi₃; 88.19/11.81; Cu; Ø75 × 6 | 100.00 | 1775 | 35 |
| 24 | TiB₂/TisSi₃/SiB₆; 58.89/15.44/25.67; Cu; Ø75 × 6 | 100.00 | 1300 | 35 |
| 25 | TiB₂/TisSi₃/SiB₆; 67/17/16; Cu; Ø75 × 6 | 100.00 | 1350 | 35 |
| 26 | TiB₂/TisSi₃/SiB₆; 77.12/8.58/14.3; Cu; Ø75 × 6 | 100.00 | 1300 | 35 |
| 27 | TiB₂/TiSi₂; 80/20; Cu; Ø75 × 6 | 98.44 | 1400 | 30 |
| 28 | TiB₂/TiSi₂; 90/10; Cu; Ø75 × 6 | 98.08 | 1360 | 30 |

### PRODUCTION EXAMPLES 1 TO 28

To produce the targets the starting powders are weighed out in the specified ratio given in the table above after conversion of the mol % proportions into wt % proportions and homogenized and mixed in a freefall mixer with addition of steel balls in isopropanol. The mixture is subsequently dried in a furnace, filled into a graphite tool and this is introduced into a spark plasma sintering apparatus. The mixture is then brought to the specified operating temperature over about 30 minutes while simultaneously building up the specified operating pressure. The mixture was uniaxially densified for about 1 h under these conditions. The densification took place without occurrence of liquid phases.

As is apparent from the table the pressed compacts all have very high densities and thus are very suitable as evaporation sources. The pressed compact was subsequently joined to the specified support element. In the case of a Mo backplate this was produced separately and joined by hard soldering using a Ticusil® foil as the soldering medium or using Ti, Cu and Ag as a CGS layer. In the case of a copper backplate this was joined to the pressed compact of the target material by indium bonding. The plate-shaped support element and the rear side of the compacted target material are wetted with molten indium, then the wetted areas are positioned relative to one another and cooled to room temperature. During this process the molten indium solidifies and creates a connection between the support element and the densified target material.

1-16. (canceled)

17. An evaporation source, comprising:
a target material containing at least one boride selected from the group consisting of: TiB₂, W₂B₅, TaB₂, VB₂, NbB₂, CrB₂, MoB and HfB₂, at least one silicon-containing compound selected from the group consisting of: TiSi₂, Ti₅Si₃, CrSi₂, Cr₅Si₃, Cr₃Si, CeSi₂, SiB₆, HfSi, Hf₅Si₄, Hf₅Si₂, NbSi₂, Nb₅Si₃, MoSi₂, MosSi₃, Mo₃Si, ZrSi, Zr₂Si, Zr₅Si₃, Zr₅Si₄, Zr₃Si₂, TaSi₂, Ta₅Si₃, Ta₃Si, Ta₂Si, W₅Si₃ and WSi₂ and unavoidable impurities, wherein a proportion of silicon in said target material is at % to 30 at %.

18. The evaporation source according to claim 17, wherein said at least one boride and said at least one silicon-containing compound are present in said target material as separate phases and wherein a proportion of mixed phases is below 20%.

19. The evaporation source according to claim 17, wherein said at least one silicon-containing compound is one of at least two silicon-containing compounds and one of said silicon-containing compounds is SiB₆.

20. The evaporation source according to claim 19, wherein a proportion of said SiB₆ in said target material is in a range from 10 to 30 mol %.

21. The evaporation source according to claim 17, wherein:
said at least one boride is selected from the group consisting of: TiB₂, TaB₂, CrB₂, MoB and HfB₂; and
said at least one silicon-containing compound is selected from the group consisting of Ti₅Si₃, Cr₃Si, Cr₅Si₃, CeSi₂, SiB₆, HfSi, Hf₃Si₂, Hf₅Si₄, Nb₅Si₃, MoSi₂, MosSi₃, Mo₃Si, ZrSi, Zr₅Si₃, Zr₅Si₄, Zr₃Si₂, TaSi₂, Ta₅Si₃, Ta₃Si, Ta₂Si, W₅Si₃ and WSi₂ and mixtures thereof.

22. The evaporation source according to claim 17, wherein said target material is selected from the group consisting of: CrB₂/CrSi₂, CrB₂/MoSi₂; HfB₂/CeSi₂; HfB₂/MoSi₂; TiB₂/MoSi₂; TiB₂/TaSi₂; TiB₂/Ti₅Si₃; TiB₂/Ti₅Si₃/SiB₆ and TiB₂/TiSi₂.

23. The evaporation source according to claim 17, wherein said target material forms a ternary system consisting of boron, said silicon and one metal.

24. The evaporation source according to claim 17, wherein said target material has a density of at least 95% of a theoretical density.

25. The evaporation source according to claim 17, further comprising a support element.

26. The evaporation source according to claim 17, wherein said at least one boride and said at least one silicon-containing compound are present in said target material as separate phases and wherein a proportion of mixed phases is in a range from 1% to 10%.

27. The evaporation source according to claim 21, wherein said at least one boride is selected from the group consisting of: HfB₂, TiB₂ and CrB₂ and mixtures thereof.

28. A process for producing an evaporation source, which comprises the steps of:
providing a powder mixture of a target material formed from at least one boride and at least one silicon-containing compound; and
uniaxially densifying the powder mixture in a pressing tool at such temperatures and at a pressure that sintering of the powder mixture to a solid occurs without a formation of liquid phases.

29. The process according to claim 28, wherein the process is a spark plasma sintering process where the powder mixture is subjected to an electric current during densification.

30. The process according to claim 28, which further comprises carrying out the densifying step with the pressure in a range from 20 to 80 MPa and the temperature in a range from 1,300° C. to 2,200° C.

31. The process according to claim 28, which further comprises carrying out the densifying step with the pressure in a range from 25 to 60 MPa and the temperature in a range from 1,500° C. to 2,200° C.

32. The process according to claim 28, which further comprises carrying out the densifying step with the pressure in a range from 25 to 60 MPa and the temperature in a range from 1650° C. to 2200° C.

33. The process according to claim 28, which further comprises carrying out the densifying step with the pressure in a range from 25 to 60 MPa and the temperature in a range from 1800° C. to 2200° C.

34. The process according to claim 28, wherein an average particle size of starting powders is 1 μm to 50 μm for the at least one boride and 2 μm to 100 μm for the at least one silicon-containing compound.

35. The process according to claim 28, which further comprises joining the solid to a support element
